(19) United States
(12) Patent Application Publication
(10) Pub. No.: US 2011/0049639 A1
(43) Pub. Date: Mar. 3, 2011

(54) INTEGRATED CIRCUIT MANUFACTURING METHOD AND INTEGRATED CIRCUIT

(75) Inventors: Gerben Doornbos, Kessel-lo (BE); Marcus J.H. Van Dal, Heverlee (BE)

(73) Assignee: NXP B.V., Eindhoven (NL)

(21) Appl. No.: 12/989,478

(22) PCT Filed: Apr. 24, 2009
(86) PCT No.: PCT/IB2009/051692

§ 371 Date: Oct. 25, 2010

(30) Foreign Application Priority Data
Apr. 29, 2008 (EP) 08103775.6

(51) Int. Cl. H01L 27/088; H01L 21/336

(52) U.S. Cl. 257/368; 438/283; 257/E27.06; 257/E21.409

(57) ABSTRACT

A method is disclosed of manufacturing an integrated circuit. The method comprises providing a substrate (100) comprising a source region (102) and a drain region (104) separated by a channel region (106, 406), said channel region being covered by a gate stack separated from the channel region by a dielectric layer (110), the gate stack comprising a metal portion (112) over the dielectric layer (110) and a polysilicon portion (116) over the metal portion (112); implanting an oxide reducing dopant (130) into the polysilicon portion (116); depositing a silicidation metal (140) over the implanted polysilicon portion (116); and converting the implanted polysilicon portion (116) into a suicide portion. By fully converting the polysilicon portion (116) into a suicide portion, the dopant (130) is ‘snow-ploughed’ towards the interface between the metal portion (112) and the polysilicon portion (116) where it reacts with any oxide formed at said interface. This yields an IC having a plurality of transistors, which gates have a low enough contact resistance to facilitate radio frequency operating speeds.

The present invention relates to a method of manufacturing a transistor, the method comprising providing a substrate comprising a source and drain region connected by a channel region, said channel region being covered by a gate stack separated from the channel region by a dielectric layer, the gate stack comprising a metal portion over the dielectric layer and a polysilicon portion over the metal portion.

The present invention further relates to an integrated circuit comprising a plurality of transistors, each transistor comprising a channel region connecting a source region to a drain region, the channel region being covered by a dielectric layer and a gate stack comprising a metal portion and a silicide portion.

The shrinkage of feature sizes in integrated circuits (ICs) such as CMOS ICs is accompanied by a large number of challenges that have to be overcome in order to provide an IC that can operate in accordance with demanding operating requirements. For instance, the reduction in the transistor gate dielectric thickness increases the direct tunneling of carriers through the ultra-thin gate dielectric. This is becoming a major obstacle in further CMOS scaling.

Several solutions have been proposed to reduce such tunneling effects. Most solutions focus on replacing the conventional dielectric layer with a high-k dielectric layer. The high-k layer has higher dielectric constant than SiO₂ so that it can be physically thicker, thus increasing the tunneling energy barrier, and reducing leakage as a consequence. However, the combination of a high-k dielectric and a poly-Si gate is not considered to be feasible. For this reason, it has been proposed to replace the SiO₂/polysilicon (poly-Si) gate stack by a high-k dielectric/metal gate stack. The metal gate also avoids the effect of poly-Si depletion, resulting in higher inversion capacitance and hence more performance.

The replacement of the poly-Si layer entirely with a solid metal layer would solve the aforementioned problems as long as a metal with a suitable work function is selected. However, the patterning of solid metal gates is far from trivial. Alternatively, a poly-Si gate may be formed on the gate dielectric, which is replaced by a metal gate using a Damascene process. A drawback of such an approach is that it is requires a relatively large number of process steps, thus making the gate forming process quite costly.

Hence, for reasons of manufacturability, multi-layer gate architectures have been proposed, such as a metal-inserted polysilicon (MIPS) gate, in which a thin (5-10 nm) metal layer such as a TiN, TaN, W or MoON layer, is covered by a thick (100 nm) polysilicon layer which is partly converted into silicide. However, such gate architectures can suffer from an increased gate resistance compared to poly-Si gates. This causes a different problem, because the gate resistance is well-known to degrade performance at high transistor operating frequencies, for instance radio frequency (RF), where a substantial gate resistance can affect RF figures of merit. RF CMOS transistors typically operate in the 100 GHz frequency range. CMOS scaling has also pushed the digital clock speed into the GHz domain, which implies that individual transistors switch at frequencies well in excess of 100 GHz. Indeed, typical ring oscillator delays per stage are in the range of 10 ps, equivalent to 100 GHz. Therefore, it can be expected that gate resistance will degrade digital switching speed.

The gate resistance R_{gate} is in nature a distributed quantity, containing gate layer material parameters and dimensions of the gate layers between the gate contact and the gate dielectric. A good approximation is given by the following formula:

$${R}_{gate} = \frac{{ρ}_{silicide} \cdot W}{12 L} + \frac{{\sum }_{interfaces} {ρ}_{c}}{W \cdot L}$$

where L and W are the length and width of a gate line, ρ_{c} is the contact resistance between different layers in the gate electrode and ρ_{silicide} is the silicide sheet resistance.

For a poly-Si gate stack, consisting of about 100 nm heavily doped polysilicon which is partly converted into silicide such as CoSi or NiSi, typical parameter values are ρ_{silicide}=6Ω/square and ρ_{c}=3Ω·μm² for the NiSi to polysilicon interface. For transistor dimensions of L=25 nm and W=0.4 μm, which are typical transistor dimensions in a 32 nm CMOS technology, this results in a gate resistance R_{POLY}≈300Ω.

For an advanced MIPS gate stack consisting of a thin metal layer covered by a thick layer of polysilicon which is partly converted into NiSi, an additional contact resistance ρ_{c}=20Ω·μm² for the polysilicon to gate metal interface must be accounted for. For a transistor of L=25 nm and W=0.4 μm, this results in a much higher gate resistance R_{MG}≈2.3 kΩ. Hence, it can be seen that although such MIPS gates in combination with high-k dielectrics may successfully address the tunneling problem associated with poly-Si gates on SiO₂, the MIPS gates are likely to exhibit serious performance issues at GHz operating frequencies of the transistor comprising one or more of such gates.

In the paper ‘Metal Inserted Poly-Si (MIPS) and FUSI Dual Metal (TaN and NiSi) CMOS integration’ by R. Singamalla et al. in 2008 Institution of Engineering and Technology, April 2007, pages 45-46, a CMOS device is disclosed in which the n-type field-effect transistor (FET) comprises a gate stack of a TaN metal portion covered by a poly-Si portion that has been fully silicided using Ni as the silicidation metal. The metallic nature of the silicide reduces the additional contact resistance of the metal/poly-Si interface, which improves the high-frequency characteristics of the transistor.

However, it has been found that it is very difficult to avoid the formation of a thin oxide layer at the metal/poly-Si or metal/silicide interface, which causes the metal-silicide gate stack to act as a metal-insulator-metal capacitor, and which introduces a undesirable contact resistance with the metal portion and the silicide portion respectively.

The present invention seeks to provide a method of manufacturing an IC that can operate in a GHz range.

The present invention further seeks to provide an IC that can operate in the GHz range.

According to an aspect of the present invention, there is provided a method of manufacturing a transistor, comprising providing a substrate comprising a source and drain region separated by a channel region, said channel region being covered by a gate stack separated from the channel region by a dielectric layer, the gate stack comprising a metal portion over the dielectric layer and a polysilicon portion over the metal portion; implanting an oxide reducing dopant into the polysilicon portion; depositing a silicidation metal over the implanted polysilicon portion; and converting the implanted polysilicon portion into a silicide portion.

The introduction of an oxide-reducing dopant, such as Al, Ti or Yb prior to the silicidation step ensures that the oxide-reducing dopant is driven through the poly-Si during the silicidation process. This is also known as the snow-plough effect. Hence, by fully siliciding the poly-Si, the oxide reducing dopant is pushed to the thin oxide layer at the interface between the poly-Si portion and the metal portion, where it reacts with the thin oxide layer, thus reducing the contact resistance between the silicide portion and the metal portion of the gate stack.

The source and drain region may be protected from silicidation. This may for instance be achieved by depositing a masking layer over the source region and the drain region prior to said implanting step, and wherein the step of depositing the silicidation metal comprises depositing the silicidation metal over the polysilicon portion and the masking layer, the method further comprising removing unreacted silicidation metal following the converting step.

In an embodiment, the masking layer is deposited by means of spin-coating. Because spin-coating allows for excellent control of the thickness of the deposited layer, the making layer may be deposited without covering the poly-Si portion of the gate stack, thus obviating the need for further process steps such as a planarization step to expose the poly-Si portion.

The source and drain regions may also be silicided. This may be done in a separate silicidation step, in which case the method may comprise providing a mask over the polysilicon portion; siliciding the source region and the drain region; and removing said mask prior to said implanting step.

Alternatively, the source and drain regions may be silicided at the same time as the poly-Si portion of the gate stack. To this end, the method may comprise removing the masking layer following said implanting step, and wherein said depositing step comprises depositing the silicidation metal over the polysilicon portion, the source region and the drain region, and wherein said converting step comprises simultaneously converting the polysilicon portion into a silicide portion, the source region into a silicide source region and the drain region into a silicide drain region.

If necessary, the thickness of the poly-Si layer portion may be reduced prior to the removal of the masking layer. This reduces the duration of the subsequent silicidation step due to the fact that less poly-Si has to be silicidized.

The method of the present invention may be applied to both planar transistors and non-planar transistors, e.g. fin-shaped transistors such as FinFETs, and may be applied to single gate and multiple gate transistors.

According to a further aspect of the present invention, there is provided an integrated circuit comprising a plurality of transistors, each transistor comprising a channel region connecting a source region to a drain region, the channel region being covered by a dielectric layer and a gate stack comprising a metal portion and a silicide portion, wherein the interface between the metal portion and the silicide portion has been chemically altered by an implanted species, thereby lowering the resistance of the interface. The transistors of such an IC are typically characterized by the accumulation of an oxide-reducing dopant near said interface.

Such an IC, which may be integrated in a suitable electronic device, has transistors that can be operated at radio frequencies, e.g. 100 GHz.

Embodiments of the invention are described in more detail and by way of non-limiting examples with reference to the accompanying drawings, wherein

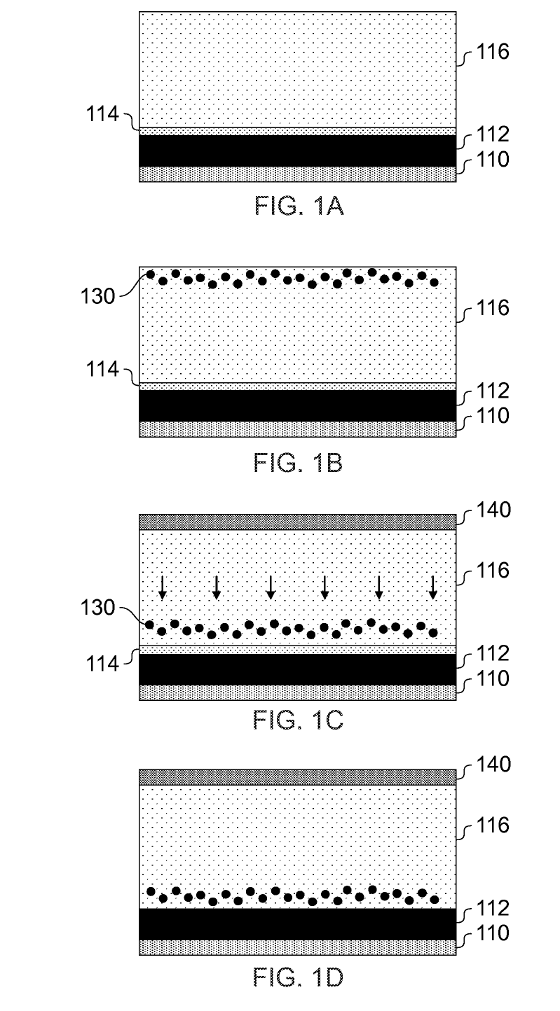

FIG. 1 a-d schematically depict the inventive concept of the present invention;

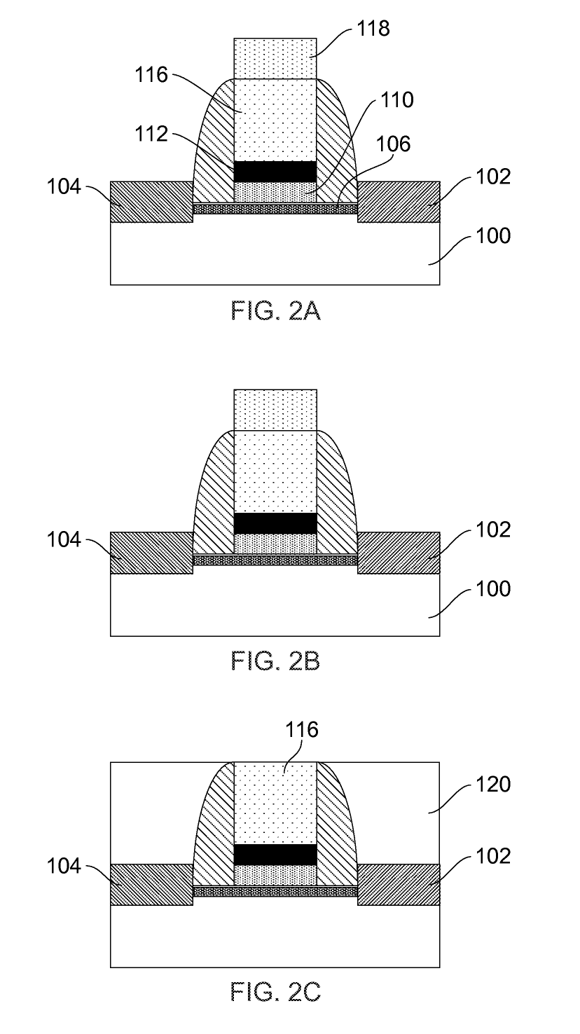

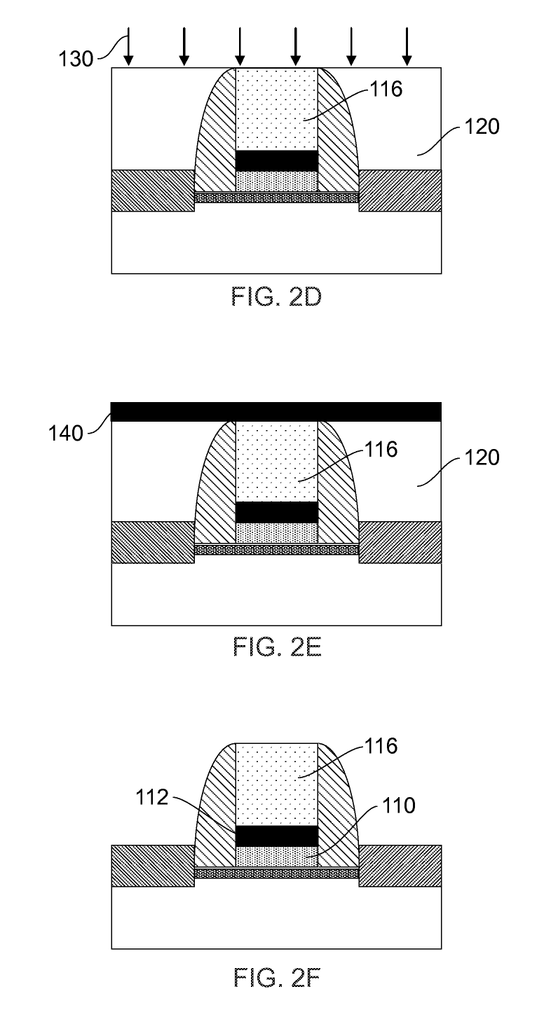

FIG. 2a-f schematically depict an embodiment of the method of the present invention;

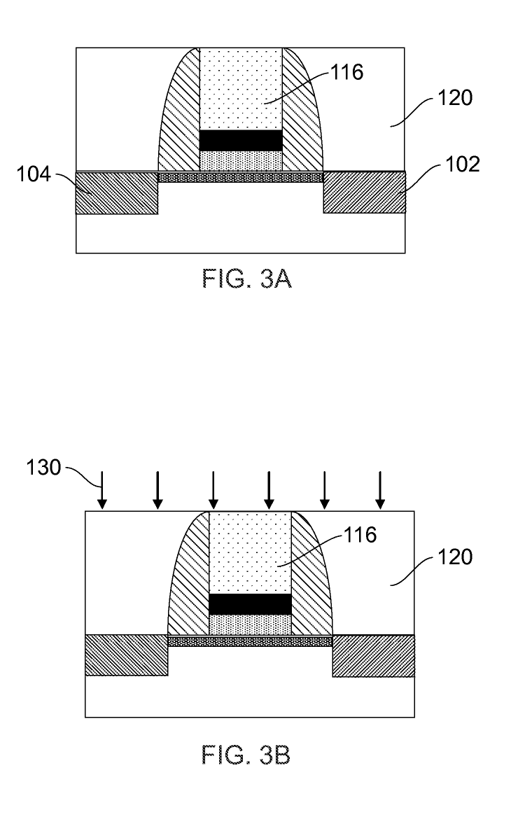

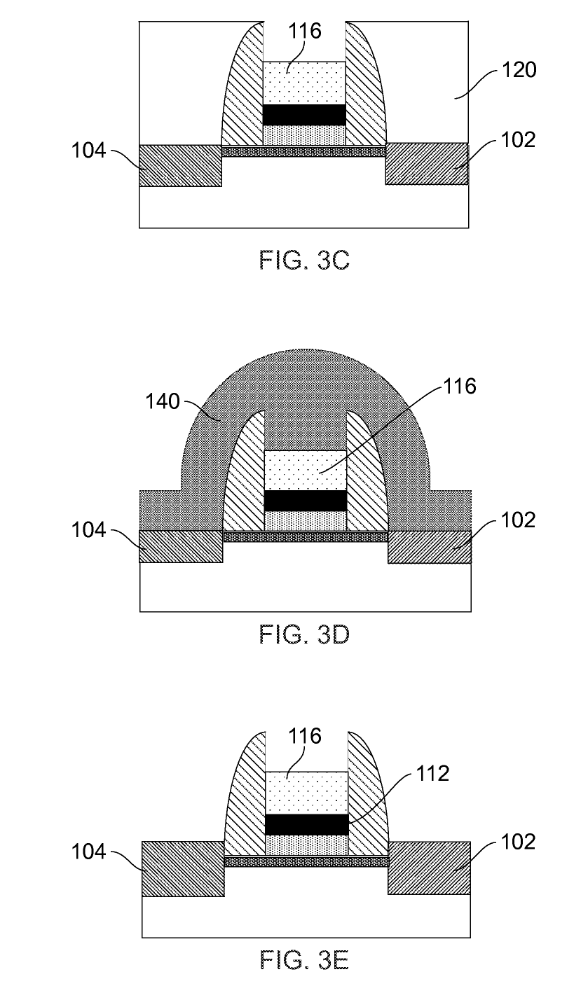

FIG. 3a-e schematically depict another embodiment of the method of the present invention; and

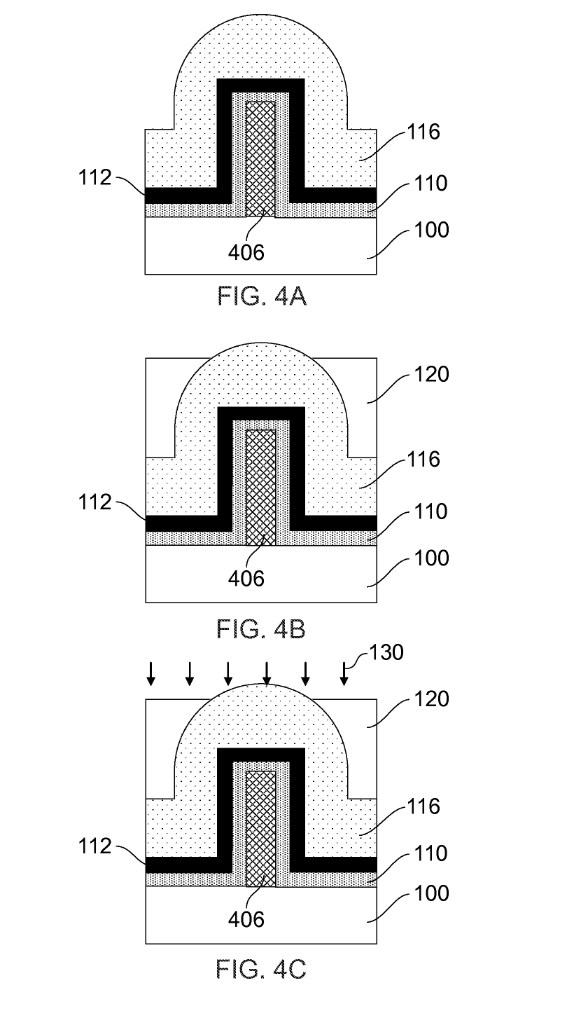

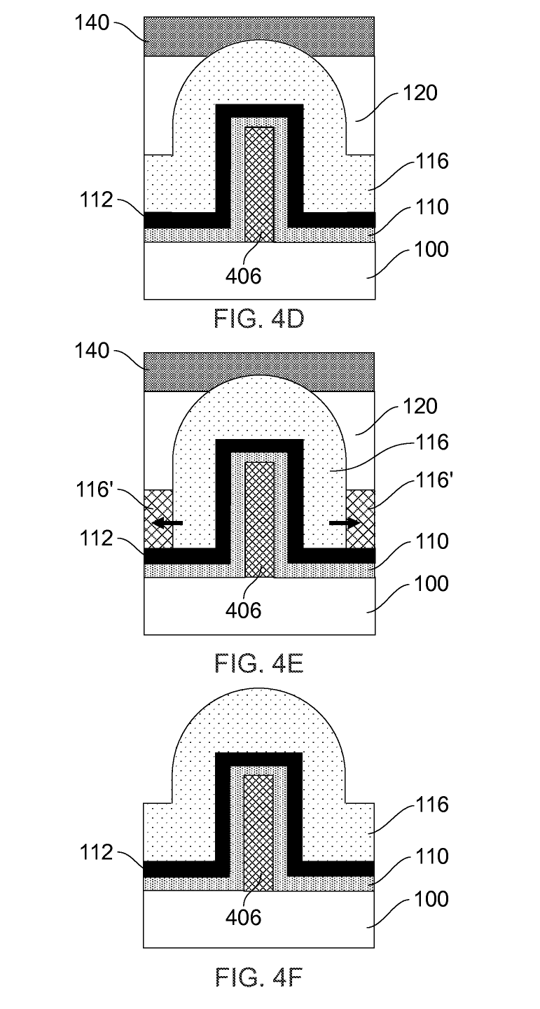

FIG. 4a-f schematically depict yet another embodiment of the method of the present invention.

It should be understood that the Figures are merely schematic and are not drawn to scale. It should also be understood that the same reference numerals are used throughout the Figures to indicate the same or similar parts.

FIG. 1a depicts a cross-section of a MIPS gate stack on a dielectric layer 110. The gate stack comprises a thin metal layer 112, which for instance may be several nanometers, e.g. 5-10 nm, thick. The metal layer 112 is covered by a poly-Si layer 116, which may be an order thicker than metal layer 112, e.g. several tens of nanometers, e.g. 50-100 nm, thick. The manufacturing of such a MIPS gate stack is well-known to the skilled person and will therefore not be discussed in further detail for reasons of brevity. In the formation of the MIPS gate stack, it is very difficult to avoid the formation of a thin oxide layer 114 between the metal layer 112 and the poly-Si layer 116. The oxide may be formed by the partial oxidation of the metal layer 112 and/or the poly-Si layer 116.

This oxide layer 114 increases the contact resistance between the metal layer 112 and the poly-Si layer 116, which impairs the high-frequency operation of a transistor controlled by the MIPS gate. In accordance with an embodiment of the present invention, a dopant 130 is implanted into the poly-Si layer 116, as shown in FIG. 1b. This dopant is chosen such that it can react with the oxide layer 114, thereby converting the oxide layer into a further layer having a lower resistance than the oxide layer 114. The exact chemical reaction leading to the lower interface resistance is experimentally very difficult to establish. However, it is likely that the oxide layer 114 contains a large number of Si-O bonds, i.e. is SiO₂ like. By implanting a metallic dopant 130 such as Al, Ti, Y or other suitable dopants, the SiOₓ layer 114 is converted by the reaction:

M+SiOₓ [symbol] MO_{y}+Si
The converted layer has a significantly lower resistance. This may be because MO_{y} has a lower resistivity than SiOₓ, or because the reaction causes the agglomeration of the reaction product into islands, thus leaving a large fraction of the interface essentially oxide-free.

The dopant 130 can be migrated towards the oxide layer 114 at the interface between the metal layer 112 and the poly-Si layer 116 using the snow-plough effect of a silicidation conversion of the poly-Si layer 116, as shown in FIG. 1c. To this end, a silicidation metal 140 is deposited over the poly-Si layer 116, after which the gate stack is subjected to a thermal budget, i.e. an elevated temperature for a predefined period of time. During the silicidation reaction, the silicidation front in the poly-Si layer progresses from the silicidation metal 140 towards the oxide layer 114, thereby pushing the dopant 130 forward.

The thermal budget is chosen such that the whole poly-Si layer 116 is converted into a silicide, which ensures that the dopant 130 reaches the oxide layer 114. At the oxide layer 114, the dopant 130 reacts with the oxide as previously explained, yielding a metal-silicide gate stack as shown in FIG. 1D, where the metal-silicide interface is substantially free of oxide, thus yielding a gate that can be operated at radio frequencies.

The above principle may be applied to any suitable MIPS gate stack, such as a planar gate stack or a non-planar gate stack such as the gate stack of a FinFET. FIG. 2a-f depict an embodiment of the method of the present invention, in which the above principle is applied to a planar gate stack.

FIG. 2a shows a cross-section of an intermediate structure in an IC manufacturing process. A substrate 100, which may be any suitable substrate such as a bulk-Si wafer or a silicon on insulator (SOI) wafer. The substrate 100 comprises a source region 102, a drain region 104 and a channel region 106. A gate stack as shown in FIG. 1a is formed over the channel region 106, comprising a dielectric layer 110, a metal portion 112 and a poly-Si portion 116. It should be understood that the oxide layer 114 is not shown for reasons of clarity only.

The dielectric layer 110 may for instance comprise SiO₂, SiON or any suitable high-k dielectric material. The metal portion 112 may for instance comprise TiN, TaN, W, MoON or any other suitable metal. Since it is well-known to the skilled person how to manufacture the intermediate structure in FIG. 1a, this will not be explained in further detail for reasons of brevity only.

In an embodiment, the source region 102 and the drain region 104 may be silicided. To this end, a mask 118 may be formed over the poly-Si portion to facilitate the selective silicidation of the source region 102 and the drain region 104. The source region 102 and the drain region 104 are subsequently silicided, as shown in FIG. 2b. The deposition of the silicidizing metal prior to the silicidation of these regions is not shown.

Next, as shown in FIG. 2c, a protective layer 120 is deposited over the substrate 100. This layer may for instance be a SiO₂ layer. The deposition of the protective layer 120 may be followed by a planarization step (not shown) to etch-back the protective layer 120 such that the poly-Si portion 116 is exposed. The planarization step may be performed using any suitable technique, e.g. chemical mechanical planarization (CMP). In an alternative embodiment, the protective layer 120 is spin-coated onto the substrate 100. The protective layer may be a polymer, e.g. polyimide or may be a SiO₂ layer formed by means of a spin-on-glass technique. Spin-coating facilitates selective deposition of the protective layer 120 such that the poly-Si portion 116 of the gate stack will not be covered by the protective layer 120, thus obviating the need for a subsequent etch-back step.

In a next step, shown in FIG. 2D, the dopant 130 is implanted into the poly-Si portion 116, after which the silicidation metal 140 is deposited over the protective layer 120 and the poly-Si portion 116, as shown in FIG. 2e. Any suitable metal, e.g. Ni, Co, Pt or Ti may be used as the silicidation metal 140. The stack is subsequently exposed to a thermal budget ensuring that the poly-Si portion is fully silicided, such that the dopant 130 reaches the interface between the metal portion 112 and the poly-Si portion 116, where it reacts with the unwanted oxide layer (not shown), as previously explained. Any unreacted silicidation metal 140 is subsequently removed from the substrate stack.

Finally, the protective layer 120 is removed as shown in FIG. 2f to yield a transistor having a gate stack in accordance with an embodiment of the present invention. The protective layer 120 may be removed in any suitable way, e.g. by means of a selective etch step.

The IC manufacturing process may be completed in any suitable way. Since this is not relevant to the present invention, and since subsequent process steps will be apparent to the skilled person, these steps will not be discussed in detail for reasons of brevity only.

In FIG. 2, the poly-Si portion 116 and the source and drain regions 102, 104 have been converted into a silicide in separate steps. However, it is equally feasible to simultaneously convert the poly-Si portion 116 and the source and drain regions 102, 104 into a silicide in a self-aligned process by altering the sequence of the process steps of FIG. 2. An example of such a process in shown in FIG. 3.

In FIG. 3a, the substrate 100 is covered by the protective layer 120 such that the source region 102 and the drain region 104 are protected by the protective layer 120 and the poly-Si portion 116 is still exposed.

The poly-Si portion 116 is subsequently implanted with the dopant 130, as shown in FIG. 3b.

Optionally, the poly-Si portion 116 may be etched back to reduce the thickness of the poly-Si portion 116, as shown in FIG. 3c. The implantation of the dopant 130 may be performed before or after etching back the poly-Si portion 116. Obviously, in case of the dopant 130 being implanted before the etch-back step, the dopant must be implanted deep enough not to be removed by the etch-back.

In a next step, the protective layer 120 is removed and the silicidation metal 140 is deposited over the poly-Si portion 116 and the source and drain regions 102, 104, as shown in FIG. 3d. The intermediate device is subsequently exposed to the thermal budget for fully converting the poly-Si portion 116, as well as the source region 102 and the drain region 104, into a silicide, thereby pushing the dopant 130 towards the interface between the metal portion 112 and the poly-Si portion 116. Any unreacted silicidation metal 140 is subsequently removed, thus yielding the intermediate device in FIG. 3e, which again may be completed using conventional (back-end) processing steps.

The above methods are not limited to planar transistors, but may also be applied to a non-planar transistor such as a FinFET.

FIG. 4a depicts a cross-section an intermediate structure in the manufacturing of a FinFET device. The substrate 100 carries a fin 406 which is covered by a dielectric layer 110 and a gate stack comprising a metal layer 112 and a poly-Si layer 116. The thin oxide layer between the metal layer 112 and a poly-Si layer 116 is not shown for reasons of clarity only. The source and drain regions of this intermediate structure are also not shown in FIG. 4a. The source and drain regions may already have been silicided during which the poly-Si layer 116 has been protected by e.g. a poly-Si mask, as previously explained.

In a next step, the poly-Si layer 116 is covered by the protection layer 116 such that only the top of the poly-Si layer 116 is exposed. If required, the protection layer 116 may be etched back to expose the top of the poly-Si layer 116 as previously explained.

The top of the poly-Si layer 116 is subsequently implanted with the dopant 130, as shown in FIG. 4c, after which the silicidation metal 140 is deposited over the protective layer 120 and the top of the poly-Si layer 116. The intermediate device is subsequently subjected to a thermal budget such that the poly-Si layer surrounding the fin 406 is fully converted to a silicide. This silicidation step causes the dopant 130 to ‘snow-plough’ towards the thin oxide layer between the metal layer 112 and the poly-Si layer 116, where it reacts with the oxide as previously explained. The thermal budget may be chosen such that the silicidation process extends laterally into portions 116′ of the poly-Si layer 116. Any unreacted silicidation metal 140 and the protective layer 120 are subsequently removed to yield the intermediate device shown in FIG. 4f. This device may be completed using conventional processing steps.

At this point, it is emphasized that in the context of this application, ‘fully converted to a silicide’ does not necessarily imply that the silicidized poly-Si is uniformly silicidized, and is also intended to cover embodiments in which a silicidation gradient is present in the poly-Si. For instance, at the top of the poly-Si, the conversion degree may be higher than near the interface with the metal layer 112. Also, in case of e.g. a FinFET device, the degree of conversion may be higher in the poly-Si on top of the fin compared to the poly-Si laterally to the fin.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The mere fact that certain measures are recited in mutually different dependent claims does not indicate that a combination of these measures cannot be used to advantage.

1. A method of manufacturing a transistor, comprising:
providing a substrate comprising a source region and a drain region separated by a channel region, said channel region being covered by a gate stack separated from the channel region by a dielectric layer, the gate stack comprising a metal portion over the dielectric layer and a polysilicon portion over the metal portion;
implanting an oxide reducing dopant into the polysilicon portion;
depositing a silicidation metal over the implanted polysilicon portion; and
converting the implanted polysilicon portion into a silicide portion.

2. A method according claim 1, wherein the oxide reducing dopant is selected from the group of dopants comprising Al, Ti and Yb.

3. A method according to claim 1, wherein the silicidation metal is selected from the group of metals comprising Ni, Co, Pt and Ti.

4. A method according to claim 1, further comprising depositing a masking layer over the source region and the drain region prior to said implanting step, and wherein the step of depositing the silicidation metal comprises depositing the silicidation metal over the polysilicon portion and the masking layer.

5. A method according to claim 4, wherein depositing the masking layer is performed by means of spin-coating.

6. A method according to claim 4, further comprising planarizing the masking layer prior to said implanting step to expose the polysilicon portion.

7. A method according to claim 1, wherein the channel region is fin-shaped.

8. A method according to claim 1, further comprising the steps of:
providing a mask over the polysilicon portion;
siliciding the source region and the drain region; and
removing said mask prior to said implanting step.

9. A method according to claim 1, further comprising depositing a masking layer over the source region and the drain region prior to said implanting step; and
removing the masking layer following said implanting step,
and wherein said depositing step comprises depositing the silicidation metal over the polysilicon portion, the source region and the drain region, and wherein said converting step comprises simultaneously converting the polysilicon portion into a silicide portion, the source region into a silicided source region and the drain region into a silicided drain region.

10. A method according to claim 8, further comprising back-etching the polysilicon portion prior to said removing step.

11. An integrated circuit comprising a plurality of transistors, each transistor comprising a channel region separating a source region from a drain region, the channel region being covered by a dielectric layer and a gate stack comprising a metal portion and a silicide portion, wherein the interface between the metal portion and the silicide portion has been at least partially chemically altered to lower the interface resistance.

12. An integrated circuit according to claim 11, wherein the silicide portion comprises an accumulation of an oxide-reducing dopant near said interface.

13. An integrated circuit according to claim 11, wherein each transistor comprises a plurality of gates.

14. An integrated circuit according to claim 11, wherein the source region and drain region each comprise a silicide region.

15. An electronic device comprising an integrated circuit according to claim 11.
